(19) United States
(12) Patent Application Publication
(10) Pub. No.: US 2016/0281241 A1
(43) Pub. Date: Sep. 29, 2016

(54) WATER ELECTROLYSIS SYSTEM

(71) Applicants: FUJIFILM Corporation, Tokyo (JP); JAPAN TECHNOLOGICAL RESEARCH ASSOCIATION OF ARTIFICIAL PHOTOSYNTHETIC CHEMICAL PROCESS, Tokyo (JP); THE UNIVERSITY OF TOKYO, Tokyo (JP)

(72) Inventors: Kohei HIGASHI, Kashiwa-shi (JP); Kazunari DOMEN, Tokyo (JP); Jiro TSUKAHARA, Kashiwa-shi (JP)

(73) Assignees: FUJIFILM Corporation, Tokyo (JP); JAPAN TECHNOLOGICAL RESEARCH ASSOCIATION OF ARTIFICIAL PHOTOSYNTHETIC CHEMICAL PROCESS, Tokyo (JP); THE UNIVERSITY OF TOKYO, Tokyo (JP)

(21) Appl. No.: 15/178,769

(22) Filed: Jun. 10, 2016

Related U.S. Application Data
(63) Continuation of application No. PCT/JP2014/082406, filed on Dec. 8, 2014.

(30) Foreign Application Priority Data
Dec. 13, 2013 (JP) 2013-258221

(51) Int. Cl. C25B 1/00; H01G 9/20; C25B 1/04; H01L 31/032; H01L 31/05

(52) U.S. Cl. CPC C25B 1/003; H01L 31/0322; H01L 31/0326; H01L 31/0504; C25B 1/04; H01G 9/20

(57) ABSTRACT

A water electrolysis system decomposes an aqueous electrolyte solution into hydrogen and oxygen using light. The water electrolysis system includes a plurality of photoelectric conversion units that have at least one photoelectric conversion element and receive light to generate electrical energy, and a plurality of electrolyte cells in which hydrogen gas and oxygen gas are generated by electrolyzing the aqueous electrolyte solution using the electrical energy obtained by the photoelectric conversion units. The photoelectric conversion units and the electrolyte cells are electrically connected in series. The electrolyte cells are arranged between the photoelectric conversion units, and the photoelectric conversion units or the electrolyte cells located at respective ends in an arrangement state are electrically connected together.

### CROSS-REFERENCE TO RELATED APPLICATIONS

This application is a Continuation of PCT International Application No. PCT/JP2014/082406 filed on Dec. 8, 2014, which claims priority under 35 U.S.C. §119(a) to Japanese Patent Application No. 2013-258221 filed on Dec. 13, 2013. The above application is hereby expressly incorporated by reference, in its entirety, into the present application.

### BACKGROUND OF THE INVENTION

1. Field of the Invention

The present invention relates to a water electrolysis system that receives light to electrolyze water and decompose the water into hydrogen and oxygen, using photoelectric conversion elements, and particularly, a water electrolysis system that can adjust a voltage required for electrolysis of water.

2. Description of the Related Art

In the related art, as one form of using solar light energy that is renewable energy, there is suggested a hydrogen manufacturing apparatus that utilizes electrons and positive holes obtained by photoelectric conversion using a decomposition reaction of water, using a photoelectric conversion material used for solar batteries, and thereby manufactures hydrogen used for fuel cells or the like (for example, refer to JP2004-197167A).

In the hydrogen manufacturing apparatus disclosed in JP2004-197167A, a photoelectric conversion part or a solar battery in which two pn junctions that generate an electromotive force if solar light enters are connected in series is provided, an electrolytic solution chamber is provided on a lower side of the photoelectric conversion part or the solar battery opposite to a light-receiving surface that receives solar light on an upper side of the photoelectric conversion part or the solar battery, the inside of an electrolytic chamber is divided by anion-conducting partition wall or a diaphragm, and water is electrolyzed and hydrogen is generated by the electrical energy generated in the photoelectric conversion part or the solar battery by receiving solar light.

In JP2004-197167A, a GaAs solar battery with an electromotive force of 0.9 V and a GaAs solar battery with an electromotive force of 1.7 V are used, the values of currents to be generated are equal, and the sum of the electromotive forces is made equal to or higher than an electrolysis start voltage of water, that is, equal to or higher than a voltage required for electrolysis of water.

Additionally, in JP2004-197167A, water is electrolyzed by using electrode plates connected to p-type and n-type semiconductors of the solar battery as an anode and a cathode, respectively. Thus, the conversion efficiency from solar energy to hydrogen can be made high.

### SUMMARY OF THE INVENTION

As in JP2004-197167A, water is electrolyzed by electrical energy generated in a photoelectric conversion part or a solar battery by the reception of solar light, and thereby hydrogen is generated.

For example, in a case where the voltage required for electrolysis of water is 1.8 V, and as in JP2004-197167A, in a case where a GsAs solar battery with an electromotive force of 0.9 V, and a GaAs solar battery with an electromotive force of 1.7 V are used, (0.9 V+1.7 V)−1.8 V=0.8 V is surplus, and an energy loss equivalent to 0.8 V occurs.

In addition to this, in the related art, the voltage of a power source part 102 in which photoelectric conversion elements are connected in series is adjusted, as in a related-art water electrolysis illustrated in FIG. 7. This adjustment of the voltage is made by changing the number of the serially connected photoelectric conversion elements that constitute the power source part 102. The power source part 102 is connected to a cathode 104 for generation of hydrogen and an anode electrode 106 for generation of oxygen. The cathode 104 and the anode electrode 106 are installed in a container 110 filled with water 108.

In this case, if the electromotive force per one photoelectric conversion element is set to 0.8 V, the sum of the electromotive forces is 1.6 V in two serial connections, and water cannot be electrolyzed. Meanwhile, the sum of the electromotive forces is 2.4 V in three serial connections, 0.6 V is surplus, and an energy loss equivalent to 0.6 V occurs.

In this way, there are problems in that it is difficult to guarantee an optimum electromotive force with respect to the practical electrolysis start voltage (the voltage required for electrolysis of water) of water, and surplus electrical energy corresponding to a surplus voltage with respect to the practical electrolysis start voltage of water becomes useless.

An object of the invention is to solve the problems based on the related art and provide a water electrolysis system that can adjust a voltage required for electrolysis of water and that can reduce surplus electrical energy.

In order to achieve the above object, the invention provides a water electrolysis system that decomposes an aqueous electrolyte solution into hydrogen and oxygen using light. The water electrolysis system includes a plurality of photoelectric conversion units that have at least one photoelectric conversion element and receive light to generate electrical energy; and a plurality of electrolyte cells that includes gas generating electrodes in which hydrogen gas and oxygen gas are generated by electrolyzing the aqueous electrolyte solution using the electrical energy obtained by the photoelectric conversion units. The photoelectric conversion units and the electrolyte cells are electrically connected in series. The photoelectric conversion units or the electrolyte cells located at respective ends in an arrangement state are electrically connected together.

Additionally, it is preferable that the photoelectric conversion units are arranged on the surface of an insulating substrate, the electrolyte cells are arranged on a rear surface of the insulating substrate opposite to a side where the photoelectric conversion units receive light, and a hydrogen generating electrode for generating the hydrogen gas and an oxygen generating electrode for generating the oxygen gas are included as the gas generating electrodes, and the hydrogen generating electrode and the oxygen generating electrode face each other.

It is preferable that each of the photoelectric conversion units has a plurality of photoelectric conversion elements connected in series. It is preferable that each of the photoelectric conversion elements includes an inorganic semiconductor film having a pn junction.

It is preferable that the inorganic semiconductor film has an absorption wavelength end of 800 nm or more, and for example, the inorganic semiconductor film may include a CIGS compound semiconductor or a CZTS compound semiconductor.

Additionally, it is preferable that the gas generating electrodes are provided with a catalyst electrode used for generation of the hydrogen gas, and the catalyst electrode used for generation of the hydrogen gas is made of Pt, a substance containing Pt, or Rh. Additionally, it is preferable that the gas generating electrodes are provided with a catalyst electrode used for generation of the oxygen gas, and the catalyst electrode used for generation of the oxygen gas is made of CoOₓ or IrO₂.

Moreover, it is preferable that, when the plurality of photoelectric conversion units are irradiated with light, the amounts of generated currents generated in the respective photoelectric conversion units are equal.

According to the invention, adjustment of the voltages applied to the electrolyte cells that electrolyze the aqueous electrolyte solution to generate hydrogen gas and oxygen gas becomes possible, and a surplus voltage with respect to the voltage required for electrolysis can be reduced.

Additionally, by separating the photoelectric conversion units from the gas generating electrodes, it becomes unnecessary to immerse a photoelectric conversion portion in the aqueous electrolyte solution, and degradation of performance caused by immersion can be avoided.

Moreover, since water is electrolyzed and hydrogen gas and oxygen gas are obtained within the electrolyte cells, the areas of the electrolyte cells can be made small.

### BRIEF DESCRIPTION OF THE DRAWINGS

FIG. 1 is a schematic plan view illustrating a water electrolysis system of a first embodiment of the invention.

FIG. 2 is a schematic sectional view of main parts of the water electrolysis system of the first embodiment of the invention illustrated in FIG. 1.

FIG. 3 is an equivalent circuit diagram illustrating the configuration of the water electrolysis system of the first embodiment of the invention.

FIG. 4 is a schematic plan view illustrating the configuration of a water electrolysis system of a second embodiment of the invention.

FIG. 5 is a schematic sectional view of main parts of the water electrolysis system of the second embodiment of the invention illustrated in FIG. 4.

FIG. 6A is an equivalent circuit diagram of the water electrolysis system of the embodiment of the invention, and FIG. 6B is an equivalent circuit diagram of another example of the water electrolysis system of the embodiment of the invention.

FIG. 7 is a schematic view illustrating a related-art water electrolysis apparatus.

### DESCRIPTION OF THE PREFERRED EMBODIMENTS

Hereinafter, a water electrolysis system of the invention will be described in detail with reference to preferred embodiments illustrated in the attached drawings.

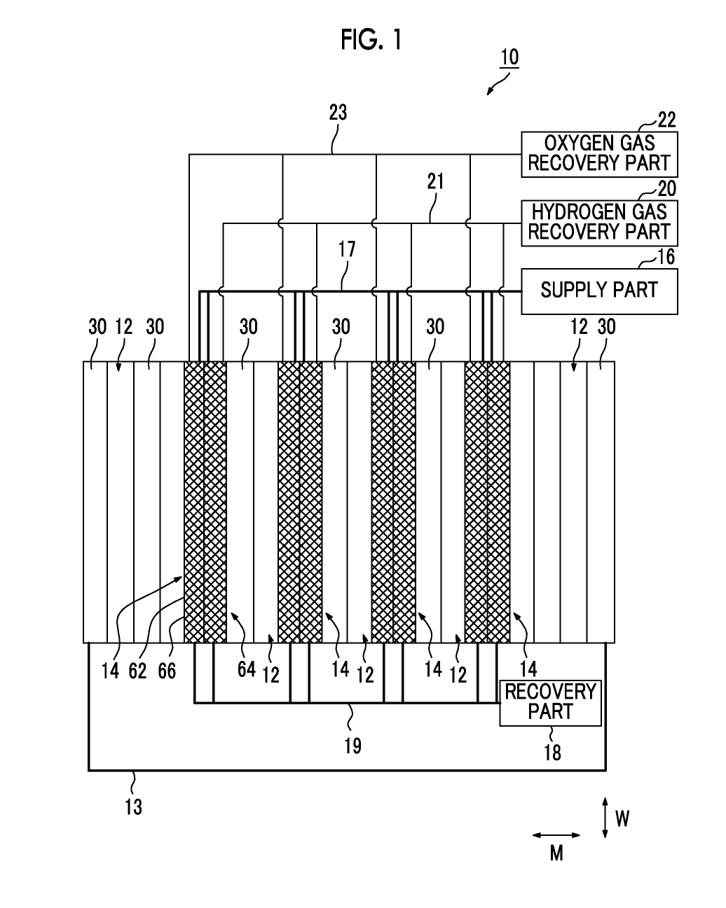

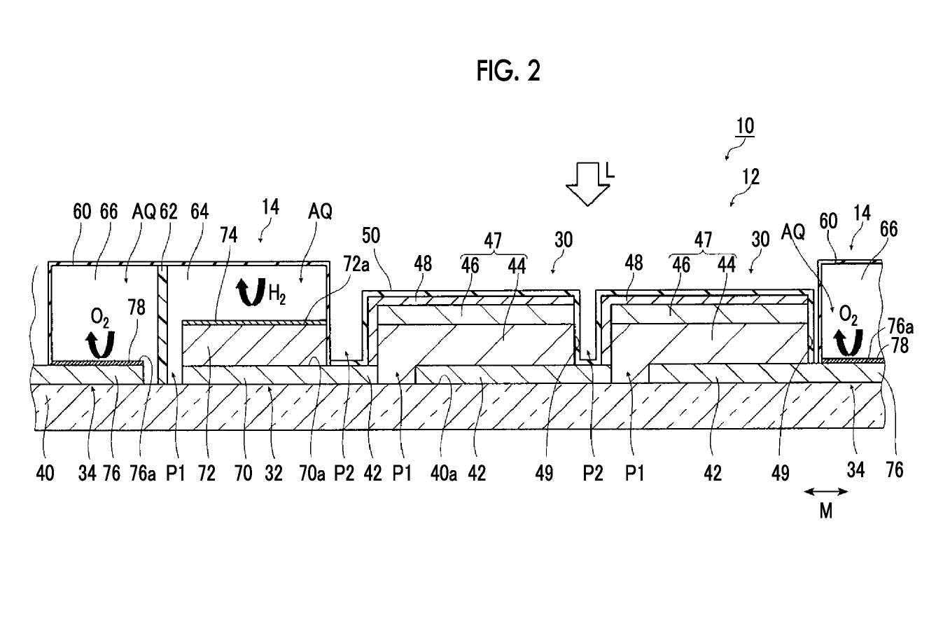

FIG. 1 is a schematic plan view illustrating a water electrolysis system of a first embodiment of the invention, and FIG. 2 is a schematic sectional view of main parts of the water electrolysis system of the first embodiment of the invention illustrated in FIG. 1.

As illustrated in FIG. 1, the water electrolysis system 10 (hereinafter simply referred to a system 10) has, for example, a plurality of photoelectric conversion units 12 and a plurality of electrolyte cells 14.

In the system 10, each electrolyte cell 14 is arranged in a direction M between the photoelectric conversion units 12, and the photoelectric conversion units 12 and the electrolyte cells 14 are electrically connected in series. The photoelectric conversion units 12 located at the respective ends in the direction M are connected together with, for example, wiring 13, in an arrangement state thereof. In addition, the photoelectric conversion units 12 located at the respective ends are not limited to being connected together via the wiring 13.

Each photoelectric conversion unit 12 is provided to receive light to generate electrical energy and to supply electrical energy for generating oxygen gas in an oxygen gas generating part 34 to be described below and electrical energy for generating hydrogen gas in a hydrogen gas generating part 32 to be described below. A generation voltage and a generated current are included in the electrical energy generated in the photoelectric conversion unit 12.

The photoelectric conversion unit 12 has at least one photoelectric conversion element 30. As will be described below, in an example illustrated in FIGS. 1 and 2, the photoelectric conversion unit 12 is a cascade type integrated element in that two or more, that is, a plurality of the photoelectric conversion elements 30 are electrically connected in series.

An aqueous electrolyte solution AQ is supplied to each electrolyte cell 14 as will be described below. In the electrolyte cell 14, the aqueous electrolyte solution AQ is decomposed using an electromotive force generated in the photoelectric conversion unit 12, and hydrogen gas and oxygen gas are generated within the electrolyte cell 14. The electrolyte cell 14 includes an electrolyte cell for hydrogen that generates hydrogen, and an electrolyte cell for oxygen that generates oxygen, and these cells are isolated from each other by a partition wall 62. The electrolyte cell 14 constitutes a gas generation region.

Here, the aqueous electrolyte solution AQ is, for example, a liquid using H₂O as a main component, may be distilled water, or may be an aqueous solution using water as a solvent and containing solute. Water, for example, may be an electrolytic solution that is an aqueous solution containing an electrolyte, or may be cooling water used in a cooling tower or the like. The electrolytic solution is, for example, an aqueous solution containing an electrolyte, and is, for example, strong alkali (KOH), a polymer electrolyte (NAFION (registered trademark)), an electrolytic solution containing 0.1 M of H₂SO₄, a 0.1-M disodium sulfate electrolytic solution, a 0.1-M potassium phosphate buffer solution, or the like.

The system 10 has a supply part 16 for supplying the aqueous electrolyte solution AQ to the electrolyte cells 14, and a recovery part 18 that recovers the aqueous electrolyte solutions AQ discharged from the electrolyte cells 14.

As the supply part 16 and the recovery part 18, a well-known water supply device, such as a pump, is available, and a well-known water recovery device, such as a tank, is available.

The supply part 16 is connected to the electrolyte cells 14 via a supply pipe 17, and the recovery part 18 is connected to the electrolyte cells 14 via a recovery pipe 19. The aqueous electrolyte solution AQ recovered by the recovery part 18 may be made to circulate through the supply part 16, and the aqueous electrolyte solution AQ may be reused.

Moreover, the system 10 has a hydrogen gas recovery part 20 that recovers the hydrogen gas generated in the electrolyte cells 14, and an oxygen gas recovery part 22 that recovers the oxygen gas generated in the electrolyte cells 14.

The hydrogen gas recovery part 20 is connected to the electrolyte cells 14 via a pipe 21 for hydrogen, and the oxygen gas recovery part 22 is connected to the electrolyte cells 14 via a pipe 23 for oxygen.

The configuration of the hydrogen gas recovery part 20 is not particularly limited if the hydrogen gas recovery part can recover hydrogen gas, and, for example, devices using an adsorption process, a diaphragm process, and the like may be used.

The configuration of the oxygen gas recovery part 22 is not particularly limited if the oxygen gas recovery part can recover oxygen gas, and, for example, a device using an adsorption process may be used.

In addition, the system 10 may be inclined at a predetermined angle with respect to a width direction W. Accordingly, the aqueous electrolyte solution AQ becomes apt to move to the recovery pipe 19 side, and the efficiency of generation of hydrogen gas and oxygen gas can be made high. The hydrogen gas and the oxygen gas become apt to move to the supply pipe 17 side, and the hydrogen gas and the oxygen gas can be recovered efficiently.

Next, a photoelectric conversion unit 12 and an electrolyte cell 14 that constitute the system 10 will be described in detail.

As illustrated in FIG. 2, the system 10 is an integrated structure having the photoelectric conversion unit 12 and the electrolyte cell 14 on a surface 40a of a planar insulating substrate 40, that is, on the same plane. The surface 40a side of the insulating substrate 40 becomes a light-receiving surface side of the photoelectric conversion unit.

The photoelectric conversion unit 12 and the electrolyte cell 14 are electrically connected in series via a back electrode 42.

As described above, the photoelectric conversion unit 12 is one in which two photoelectric conversion elements 30 are connected in series, and is arranged on the surface 40a of the insulating substrate 40. Each photoelectric conversion element 30 is configured so that the back electrode 42, a photoelectric conversion layer 44, a buffer layer 46, a transparent electrode 48, and a protective layer 50 are laminated sequentially from the insulating substrate 40 side.

In the photoelectric conversion element 30, a pn junction is formed at the interface between the photoelectric conversion layer 44 and the buffer layer 46. In addition, the photoelectric conversion layer 44 and the buffer layer 46 constitute an inorganic semiconductor film 47 having a pn junction.

The protective layer 50 is insoluble in a weak acidic solution and a weak alkaline solution, and has light permeability, water impermeability, and insulation together.

The protective layer 50 has translucency and is provided to protect the photoelectric conversion element 30, and the protective layer 50 covers the whole surface of the transparent electrode 48 and a side surface 49 of the photoelectric conversion element 30.

The protective layer 50 is made of, for example, SiO₂, SnO₂, Nb₂O₅, Ta₂O₅, Al₂O₃, Ga₂O₃, or the like. Additionally, the thickness of the protective layer 50 is not particularly limited, and is preferably 100 nm to 1000 nm.

In addition, methods for forming the protective layer 50 are not particularly limited, and the protective layer 50 can be formed by an RF sputtering method, a DC reactive sputtering method, a MOCVD method, and the like.

Additionally, the protective layer 50 may be made of, for example, insulating epoxy resin, insulating silicone resin, insulating fluororesin, or the like. In this case, the thickness of the protective layer 50 is not particularly limited and is preferably 2 μm to 1000 μm.

In the photoelectric conversion unit 12, two photoelectric conversion elements 30 are connected in series in the direction M. However, the number of photoelectric conversion elements is not limited and may be one or three or more as long as an electromotive force that can generate hydrogen gas and oxygen gas can be generated. If the plurality of photoelectric conversion elements 30 are connected in series, a higher voltage can be obtained, and a voltage generated in the entire system 10 can be adjusted. Therefore, it is preferable that the plurality of photoelectric conversion elements 30 are connected in series.

The hydrogen gas generating part 32 and the oxygen gas generating part 34 are arranged in the direction M with the photoelectric conversion unit 12 interposed therebetween, and the photoelectric conversion unit 12, the hydrogen gas generating part 32, and the oxygen gas generating part 34 are electrically connected in series.

The electrolyte cell 14 is formed by a container 60 provided on the insulating substrate 40. An electrolyte cell 64 for hydrogen and an electrolyte cell 66 for oxygen are formed by the partition wall 62 provided within the container 60. The configuration of the container 60 is not particularly limited if the container can contain the aqueous electrolyte solution AQ without leaking this solution and does not react with hydrogen gas and oxygen gas.

The hydrogen gas generating part 32 arranged within the electrolyte cell 64 for hydrogen and the oxygen gas generating part 34 arranged within the electrolyte cell 66 for oxygen are connected to separate photoelectric conversion units 12, respectively. The hydrogen gas generating part 32 and the oxygen gas generating part 34 of the photoelectric conversion units 12 adjacent to each other are arranged within the same electrolyte cell 14.

The partition wall 62 is provided to isolate the hydrogen gas generated in the electrolyte cell 64 for hydrogen and the oxygen gas generated in the electrolyte cell 66 for oxygen so that these gases are not mixed together. For this reason, if the partition wall 62 has the above-described isolation function, the configuration thereof is not particularly limited.

In addition, the partition wall 62 may be provided to separate the inside of the container 60 into the electrolyte cell 64 for hydrogen and the electrolyte cell 66 for oxygen in order to pass hydroxy ions and hydrogen ions therethrough so that the hydroxy ions (pH also increases) that has increased due to the generation of hydrogen within the electrolyte cell 64 for hydrogen and the hydrogen ions (pH decreases) that has increased due to the generation of oxygen within the electrolyte cell 66 for oxygen neutralize.

In this case, the partition wall 62 is configured to have, for example, ion permeability and gas non-permeability. Specifically, the partition wall is made of, for example, an ion exchange membrane, a ceramic filter, porous glass, or the like. The thickness of the partition wall 62 is not particularly limited, and is preferably 10 μm to 1000 μm.

The hydrogen gas generating part 32 has a region 70 to which the back electrode 42 connected to the photoelectric conversion element 30 extends, a functional layer 72 that is formed on a surface 70a of the region 70, and a catalyst electrode 74 for promoting generation of hydrogen. The catalyst electrode 74 used for generation of hydrogen gas is formed on a surface 72a of the functional layer 72.

The functional layer 72 constitutes the hydrogen gas generating part 32, and a transparent conductive protective film is used as the functional layer. The functional layer 72 is insoluble in a weak acidic solution and a weak alkaline solution, and has all of light permeability, water impermeability, and conductivity.

The functional layer 72 supplies electrons to hydrogen ions (protons) H+ ionized from a water molecule to generate a hydrogen molecule, that is, hydrogen gas, (2H⁺+2e⁻→H₂), and the surface 72a thereof functions as a hydrogen gas generation surface. Therefore, the functional layer 72 constitutes the hydrogen gas generation region.

For example, the same transparent conductive film as the transparent electrodes 48, such as ZnO in which ITO, Al, B, Ga, In, or the like is doped or IMO (In₂O₃ to which Mo is added) can be used for the functional layer 72. The functional layer 72 may be a single layer structure, similar to the transparent electrode 48, or a laminated structure, such as a two-layer structure. Additionally, the thickness of the functional layer 72 is not particularly limited, is preferably 10 nm to 1000 nm, and is more preferably 50 nm to 500 nm.

In addition, methods for forming the functional layer 72 are not particularly limited, and the functional film can be formed by vapor phase film forming methods or coating methods, such as an electron-beam vapor deposition method, a sputtering method, and a CVD method, similar to the transparent electrode 48.

It is preferable that the catalyst electrode 74 is made of, for example, metal, conductive oxide, or substances with an overvoltage of less than 0.5 V. More specifically, the catalyst electrode 74 includes, for example, simple substances consisting of Pt, Pd, Ni, Fe, Au, Ag, Ru, Cu, Co, Rh, Ir, Mn, and the like, alloys obtained by combining these simple substances, and oxides thereof, for example, NiOₓ, and RuO₂. Additionally, the size of the catalyst electrode 74 is not particularly limited, and is preferably 5 nm to 1 μm.

In addition, methods for forming the catalyst electrode 74 are not particularly limited, and the catalyst electrode can be formed by a coating baking method, an optical electrodeposition method, a sputtering method, an impregnating method, and the like.

The functional layer 72 is not necessary provided, and the catalyst electrode 74 may be directly formed on the surface 70a of the region 70. In this case, the region 70 to which the back electrode 42 extends functions as a hydrogen generating electrode, and the surface 70a thereof functions as a hydrogen gas generation surface.

Although it is preferable that the catalyst electrode 74 is provided on the surface 72a of the functional layer 72, the catalyst electrode may not be provided in a case where sufficient generation of hydrogen gas is possible.

The oxygen gas generating part 34 consists of a region 76 of an extending portion of the back electrode 42 of the photoelectric conversion element 30, and this region 76 constitutes the oxygen gas generation region and functions as an oxygen generating electrode.

Specifically, the region 76 of the extending region of the back electrode 42 of the photoelectric conversion element 30 takes out electrons from hydroxyl ions OH⁻ ionized from a water molecule, and generates an oxygen molecule, that is, an oxygen gas, (2OH⁻→H₂O+O₂/2+2e⁻), and a surface 76a thereof functions as the oxygen gas generation surface.

A catalyst electrode 78 for generation of oxygen used for generation of oxygen gas is formed on the surface 76a of the region 76 of the back electrode 42.

It is preferable that the catalyst electrode 78 for generation of oxygen is made of, for example, metal, conductive oxide, or a substance with an overvoltage of less than 0.5 V. More specifically, the catalyst electrode 78 is made of, for example, IrO₂, Ni, Co, Pt, Fe, CoOₓ, or the like. Additionally, the size of the catalyst electrode 78 for generation of oxygen is not particularly limited, and is preferably 5 nm to 1 μm.

In addition, methods for forming the catalyst electrode 78 for generation of oxygen are not particularly limited, and the catalyst electrode for generation of oxygen can be formed by a coating baking method, an immersion method, an impregnating method, a sputtering method, a vapor deposition method, and the like.

A hydrogen generating electrode and an oxygen generating electrode are collectively referred as a gas generating electrode.

Hereinafter, the respective parts that constitute the photoelectric conversion unit 12 and the electrolyte cell 14 will be described.

The insulating substrate 40 is not particularly limited if the insulating substrate has insulation and has strength such that the photoelectric conversion unit 12 and the electrolyte cell 14 can be supported. As the insulating substrate 40, for example, a soda lime glass (SLG) substrate or a ceramic substrate can be used. Additionally, one in which an insulating layer is formed on a metal substrate can be used for the insulating substrate 40. Here, as the metal substrate, a metal substrates, such as an Al substrate or an SUS substrate, or a complex metal substrate, such as a complex Al substrate made of a composite material consisting Al and, for example, with other metal, such as SUS, is available. In addition, the complex metal substrate is also a type of metal substrate, and the metal substrate and the complex metal substrate are collectively also referred to as the metal substrate. Moreover, a metal substrate with an insulating film having an insulating layer forming by anodized the surface of the Al substrate, or the like, can also be used as the insulating substrate 40. The insulating substrate 40 may be a flexible substrate or may not be such a flexible substrate. In addition, in addition to the above-described substrates, for example, glass plates, such as high strain-point glass and alkali-free glass, and a polyimide material can also be used as the insulating substrate 40.

The thickness of the insulating substrate 40 may be an arbitrary thickness without being particularly limited if the photoelectric conversion unit 12 and the electrolyte cell 14 can be supported. However, for example, the thickness of the insulating substrate may be about 20 μm to 20000 μm, is preferably 100 μm to 10000 μm, and is more preferably 1000 μm to 5000 μm.

In addition, in a case where one including a CIGS-based compound semiconductor is used for the photoelectric conversion layer 44 of the photoelectric conversion element 30, the photoelectric conversion efficiency of the photoelectric conversion element 30 are improved if alkali ions (for example, sodium (Na) ions: Na+) are supplied to the insulating substrate 40 side. Thus, it is preferable that an upper surface of the insulating substrate 40 is provided with an alkali supply layer for supplying alkali ions. In addition, for example, the alkali supply layer is unnecessary in the case of the SLG substrate.

The back electrode 42 is made of, for example, metal, such as Mo, Cr, and W, or combination thereof. The back electrode 42 may be a single layer structure, or may be a laminated structures, such as a two-layer structure. The back electrode 42 is preferably made of Mo among them. Although the film thickness of the back electrode 42 is generally about 800 nm, it is preferable that the thickness of the back electrode 42 is 400 nm to 1 μm.

As described above, in the photoelectric conversion element 30, the photoelectric conversion layer 44 is a layer in which a pn junction having the photoelectric conversion layer 44 side as a p type and having the buffer layer 46 side as an n type is formed at the interface between the photoelectric conversion layer and the buffer layer 46, and the light transmitted through and reaching the protective layer 50, the transparent electrode 48, and the buffer layer 46 is absorbed to generate a positive hole on the p side and generate an electron on the n side, and has a photoelectric conversion function. In the photoelectric conversion layer 44, the positive hole generated in the pn junction is moved from the photoelectric conversion layer 44 to the back electrode 42 side, and the electron generated in the pn junction is moved from the buffer layer 46 to the transparent electrode 48 side. The film thickness of the photoelectric conversion layer 44 is preferably 1.0 μm to 3.0 μm, and is particularly preferably 1.5 μm to 2.0 μm.

It is preferable that the photoelectric conversion layer 44 is constituted of, for example, a CIGS-based compound semiconductor or a CZTS-based compound semiconductor that has a chalcopyrite crystal structure. It is more preferable that the photoelectric conversion layer 44 is constituted of the CIGS-based compound semiconductor layer. The CIGS-based compound semiconductor layer may be made of well-known substances used for CIGS systems, such as CuInSe2 (CIS) and CuGaSe2 (CGS) as well as Cu(In, Ga) Se2 (CIGS).

In addition, as methods for a CIGS layer, 1) a multi-source vapor deposition method, 2) a selenide method, 3) a sputtering method, 4) a hybrid sputtering method, 5) mechano-chemical process method, and the like are known.

Other methods for forming the CIGS layer include a screen printing method, a proximity sublimating method, an MOCVD method, a spray method (wet film-forming method), and the like. For example, crystal with a desired composition can be obtained, for example, by forming a particulate film containing an Ib group element, a IIIb group element, and a VIb group element on a substrate, using the screen printing method (wet film-forming method), the spray method (wet film-forming method), or the like, and performing thermal decomposition processing (in this case, may be thermal decomposition processing in a VIb group element atmosphere) or the like (JP1997-74065 (JP-H09-74065) and JP1997-74213 (JP-H09-74213)).

In the invention, as described above, it is preferable that the photoelectric conversion layer 44 is constituted of, for example, the CIGS-based compound semiconductor or the CZTS-based compound semiconductor that has the chalcopyrite crystal structure. However, the invention is not limited to this, and the photoelectric conversion layer may be arbitrary photoelectric conversion elements so long as a pn junction consisting of an inorganic semiconductor can be formed, and hydrogen gas and oxygen gas can be generated by causing a photolysis reaction of water. For example, a photoelectric conversion element used for a solar battery cell that constitutes a solar battery is preferably used. Such a photoelectric conversion element includes a thin film silicon-based thin film type photoelectric conversion element, a CdTe-based thin film type photoelectric conversion element, a dye-sensitization-based thin film type photoelectric conversion element, or an organic thin film type photoelectric conversion element, in addition to a CIGS-based thin film type photoelectric conversion element, a CIS-based thin film type photoelectric conversion element and a CZTS-based thin film type photoelectric conversion element.

In addition, the absorption wavelength of an inorganic semiconductor that forms the photoelectric conversion layer 44 is not particularly limited if the absorption wavelength is in a wavelength band where photoelectric conversion is allowed. Although it is sufficient if the absorption wavelength includes the wavelength band of solar light or the like, particularly, the visible wavelength band to the infrared wavelength band, it is preferable that the absorption wavelength end of the absorption wavelength includes 800 nm or more, that is, the infrared wavelength band. This is because solar light energy can be utilized as much as possible. Meanwhile the absorption wavelength end having a long wavelength is equivalent to a band gap becoming small, and it can be expected from this that an electromotive force for assisting water decomposition decreases. As a result, since it can be expected that the number of connections to be connected in series for the water decomposition increases, it is not necessarily good that the absorption end is longer.

The buffer layer 46 constitutes the inorganic semiconductor film 47 that has the pn junction together with the photoelectric conversion layer 44 as described above. The buffer layer 46 protects the photoelectric conversion layer 44 when the transparent electrode 48 is formed, and is formed in order to transmit the light, which has entered the transparent electrode 48, through the photoelectric conversion layer 44.

It is preferable that the buffer layer 46 includes, for example, metal sulfide containing at least one kind of metallic elements selected from a group consisting of Cd, Zn, Sn, and In, such as CdS, ZnS, Zn (S, O), and/or Zn (S, O, OH), SnS, Sn (S, O), and/or Sn (S, O, OH), InS, In (S, O), and/or In (S, O, OH). The film thickness of the buffer layer 46 is preferably 10 nm to 2 μm, and is more preferably 15 nm to 200 nm. The buffer layer 46 is formed by, for example, a chemical bath deposition method (hereinafter referred to as a CBD method).

In addition, for example, a window layer may be provided between the buffer layer 46 and the transparent electrode 48. This window layer is constituted of, for example, a ZnO layer with a thickness of about 10 nm.

The transparent electrode 48 has translucency, takes light into the photoelectric conversion layer 44, makes a pair together with the back electrode 42, functions as an electrode that moves a positive hole and an electron generated in the photoelectric conversion layer 44 (an electric current flows), and functions as a transparent conductive film for connecting the two photoelectric conversion elements 30 in series.

The transparent electrode 48 is made of, for example, ZnO or ITO in which Al, B, Ga, In, or the like is doped. The transparent electrode 48 may be a single layer structure, or may be a laminated structures, such as a two-layer structure. Additionally, the thickness of the transparent electrode is not limited, and is preferably 0.3 μm to 1 μm.

In addition, methods for forming the transparent electrode are not particularly limited, and the functional film can be formed by vapor phase film forming methods or coating methods, such as an electron-beam vapor deposition method, a sputtering method, and a CVD method.

In addition, although the transparent conductive film for connecting the adjacent photoelectric conversion elements 30 in series is not necessarily limited to the transparent electrode 48, it is good to simultaneously form the same transparent conductive film as the transparent electrode 48 from the viewpoint of easiness of manufacture.

That is, a conductive film for connecting the adjacent photoelectric conversion elements 30 in series can be formed by forming the opening groove P2 reaching the surface of the back electrode 42 on the photoelectric conversion layer 44 by a laser scribe or a mechanical scribe after the buffer layer 46 is laminated, forming a transparent conductive film constituting the transparent electrode 48 on the buffer layer 46 so as to fill the opening groove P2 and then removing the transparent conductive film within each opening groove P2 by a scribe to form a slightly narrow opening groove P2 again reaching the surface of the back electrode 42, and leaving the conductive film for directly connecting the back electrode 42 and the transparent electrode 48 of the adjacent pn photoelectric conversion elements 30.

In the photoelectric conversion unit 12, if light L enters the photoelectric conversion elements 30 from the protective layer 50 side, this light L passes through the protective layer 50, each transparent electrode 48, and each buffer layer 46, and an electromotive force is generated in each photoelectric conversion layer 44, for example, an electric current (movement of a positive hole) that faces the back electrode 42 from the transparent electrode 48 is generated. For this reason, in the photoelectric conversion unit 12, the hydrogen gas generating part 32 becomes a negative electrode (a cathode for electrolysis), and the oxygen gas generating part 34 becomes a positive electrode (an anode for electrolysis). In addition, the type (polarity) of generated gases in the photoelectric conversion unit 12 varies appropriately according to the configuration of the photoelectric conversion elements 30, the configuration of the photoelectric conversion unit 12, or the like.

Next, a method for manufacturing the photoelectric conversion unit 12 will be described.

In addition, the method for manufacturing the photoelectric conversion unit 12 is not limited to a manufacturing method illustrated below.

First, for example, a soda lime glass substrate that becomes the insulating substrate 40 is prepared.

Next, for example, an Mo film or the like that becomes the back electrode 42 is formed on the surface of the insulating substrate 40 by the sputtering method using a film formation apparatus.

Next, a separation groove P1 extending in the width direction W (refer to FIG. 1) of the insulating substrate 40 is formed by scribing the Mo film at a predetermined position, for example, using the laser scribe method. Accordingly, the back electrode 42 separated from each other by the separation groove P1 is formed.

Next, for example, a CIGS film (p-type semiconductor layer) is formed as the photoelectric conversion layer 44 so as to cover the back electrode 42 and fill the separation groove P1. This CIGS film is formed by any one of the aforementioned film formation methods.

Next, for example, a CdS layer (n-type semiconductor layer) that becomes the buffer layer 46 is formed on the photoelectric conversion layer 44 by the CBD method.

Next, two opening grooves P2 that extend in the width direction W (refer to FIG. 1) of the insulating substrate 40 and reach the surface of the back electrode 42 through the photoelectric conversion layer 44 from the buffer layer 46 are formed at positions different from the formation position of the separation groove P1 in the direction M by, for example, the scribe method. In this case, a laser scribe method or a mechanical scribe method can be used as the scribe method.

Next, a ZnO:Al layer that becomes the transparent electrode 48, and has, for example, Al, B, Ga, Sb, or the like added thereto is formed by the sputtering method or the coating method so as to extend in the width direction W (refer to FIG. 1) of the insulating substrate 40 and fill each opening groove P2 on the buffer layer 46.

Next, two slightly narrow opening grooves P2 reaching the surface of the back electrode 42 are formed again, for example, by the scribe method by removing the other portion so as to leave a portion of the ZnO:Al layer within the opening groove P2. Even this case, the laser scribe method or the mechanical scribe method can be used as the scribe method.

Next, for example, an SiO₂ film that becomes the protective layer 50 is formed in the outer surfaces of the photoelectric conversion elements 30 that constitute the photoelectric conversion unit 12, the surface of the back electrode 42 on the bottom surfaces of the two opening grooves P2, and the side surfaces 49 of the photoelectric conversion elements 30 by the RF sputtering method. Accordingly, the two photoelectric conversion elements 30 can be formed.

Next, the deposit that is located at a preset position where the electrolyte cell 14 is formed and that is formed by the above-described processes is removed using, for example, the laser scribe method or the mechanical scribe method, and the region 70 of the back electrode 42 that constitutes the hydrogen gas generating part 32, and the region 76 of the back electrode 42 that constitutes the oxygen gas generating part 34 are exposed. In the region 70 and the region 76, the back electrodes 42 of the photoelectric conversion elements 30 of the photoelectric conversion units 12 different from each other extend, respectively.

Then, for example, a ZnO layer to which Al, B, Ga, Sb, or the like is added is formed as the functional layer 72 on the surface 70a of the region 70 becoming the hydrogen gas generating part 32 by the sputtering method using a patterning mask or the coating method.

Then, for example, a Pt catalyst electrode that becomes the catalyst electrode 74 for generation of hydrogen is carried in the functional layer 72 by, for example, an optical electrodeposition method.

Meanwhile, for example, a CoOₓ catalyst electrode that becomes the catalyst electrode 78 for generation of oxygen is carried in the surface 76a of the region 76 becoming the oxygen gas generating part 34 by, for example, the immersion method.

Next, the partition wall 62 is installed in the separation groove P1 between the region 70 and the region 76. Then, the container 60 that constitutes the electrolyte cell 14 is prepared, and the container 60 is arranged to surround the hydrogen gas generating part 32 and the oxygen gas generating part 34. Accordingly, the electrolyte cell 14 having the electrolyte cell 64 for hydrogen and the electrolyte cell 66 for oxygen that are isolated from each other by the partition wall 62 is formed.

Next, the system 10 can be manufactured by connecting the supply pipe 17, the recovery pipe 19, the pipe 21 for hydrogen, and the pipe 23 for oxygen to the electrolyte cells 14, and connecting these to the supply part 16, the recovery part 18, the hydrogen gas recovery part 20, and the oxygen gas recovery part 22, respectively.

In the system 10, the photoelectric conversion unit 12 is irradiated with light L and the aqueous electrolyte solution AQ is supplied from the supply part 16 to each electrolyte cell 14. As a result, the aqueous electrolyte solution AQ is decomposed in the electrolyte cell 64 for hydrogen of each electrolyte cell 14 and thereby hydrogen gas is generated, and the aqueous electrolyte solution AQ is decomposed in the electrolyte cell 66 for oxygen and thereby oxygen gas is generated. The hydrogen gas is recovered by the hydrogen gas recovery part 20 via the pipe 21 for hydrogen. The oxygen gas is recovered by the oxygen gas recovery part 22 via the pipe 23 for oxygen.

Additionally, in the system 10, by dividing the photoelectric conversion units 12 and the gas generating electrodes, it is unnecessary to dip a photoelectric conversion portion in the aqueous electrolyte solution AQ, and degradation of performance caused by immersion can be avoided.

Moreover, since the aqueous electrolyte solution AQ is electrolyzed and the hydrogen gas and the oxygen gas are obtained within the electrolyte cells 14, the areas of the electrolyte cells 14 can be made small.

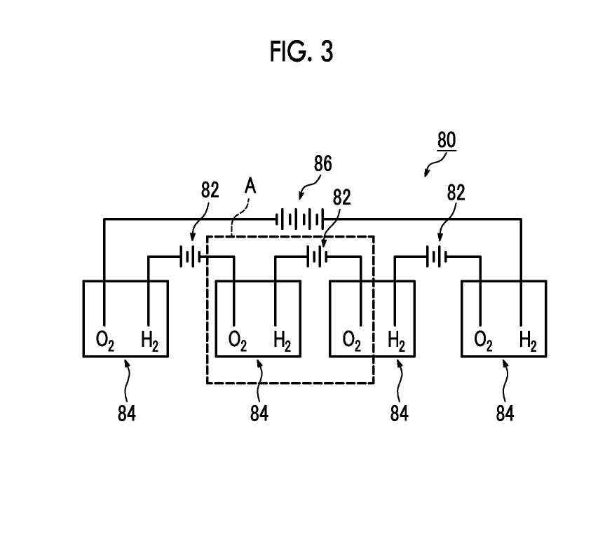

The system 10 can be expressed as an equal circuit 80 as illustrated in FIG. 3, if illustrated as an electric circuit. In the equal circuit 80, power source parts 82 are equivalent to the photoelectric conversion units 12 illustrated in FIG. 1, and electrolyte cell parts 84 are equivalent to the electrolyte cells 14 illustrated in FIG. 1. Additionally, an electromotive force part 86 connected to the electrolyte cell parts 84 at both ends is equivalent to one in which photoelectric conversion elements 30 of the photoelectric conversion units 12 at both ends illustrated in FIG. 1 are connected together with the wiring 13. One battery of a power source part 82 and the electromotive force part 86 is equivalent to one photoelectric conversion element 30.

In addition, a region A of the equal circuit 80 corresponds to the main parts of the water electrolysis system illustrated in FIG. 2.

In the equal circuit 80 illustrated in FIG. 3, ten photoelectric conversion elements 30 are connected in series. If the electromotive force of one photoelectric conversion element 30 is 0.8 V, the electromotive force of the entire system 10 is 8 V. The voltage applied to each of the four electrolyte cell parts 84 is 8 V/4 pieces, that is, 2 V/1 piece. Here, since the voltage required for electrolyzing water is 1.8 V as described above, 0.2 V is surplus for one electrolyte cell 14 and an energy loss equivalent thereto occurs.

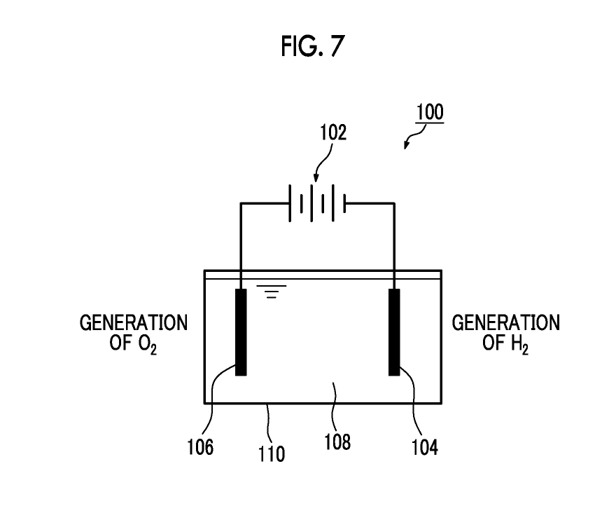

In contrast, in the related-art example illustrated in the above-described FIG. 7, an energy loss was 0.6 V. In the system 10 of the present embodiment, an energy loss can be made smaller than that of the related art. In this way, hydrogen gas and oxygen gas can be efficiently obtained. As a result, hydrogen gas can be cheaply manufactured.

Additionally, it is preferable that, when the plurality of photoelectric conversion units 12 are irradiated with light, the amounts of generated currents and generated voltages that are generated in the respective photoelectric conversion units 12 are equal. However, since a voltage with a value obtained by dividing the voltage of the entire system 10 by the number of electrolyte cells 14 is applied to the electrolyte cells 14, even if there are photoelectric conversion units having a voltage equal to or lower than a predetermined voltage among the plurality of photoelectric conversion units 12, a dropped voltage can be supplemented in the other photoelectric conversion units 12.

Next, a second embodiment of the invention will be described as an ideal configuration.

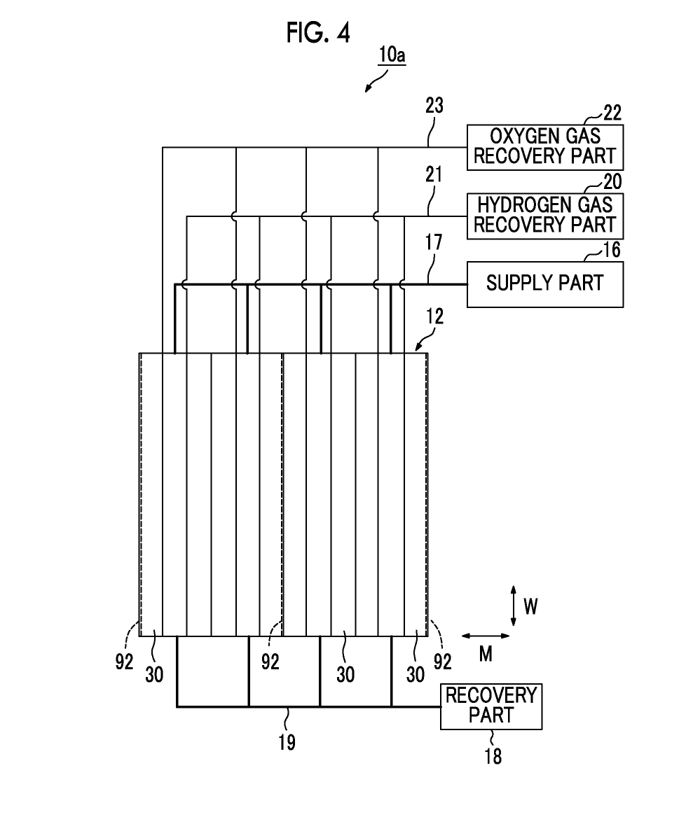

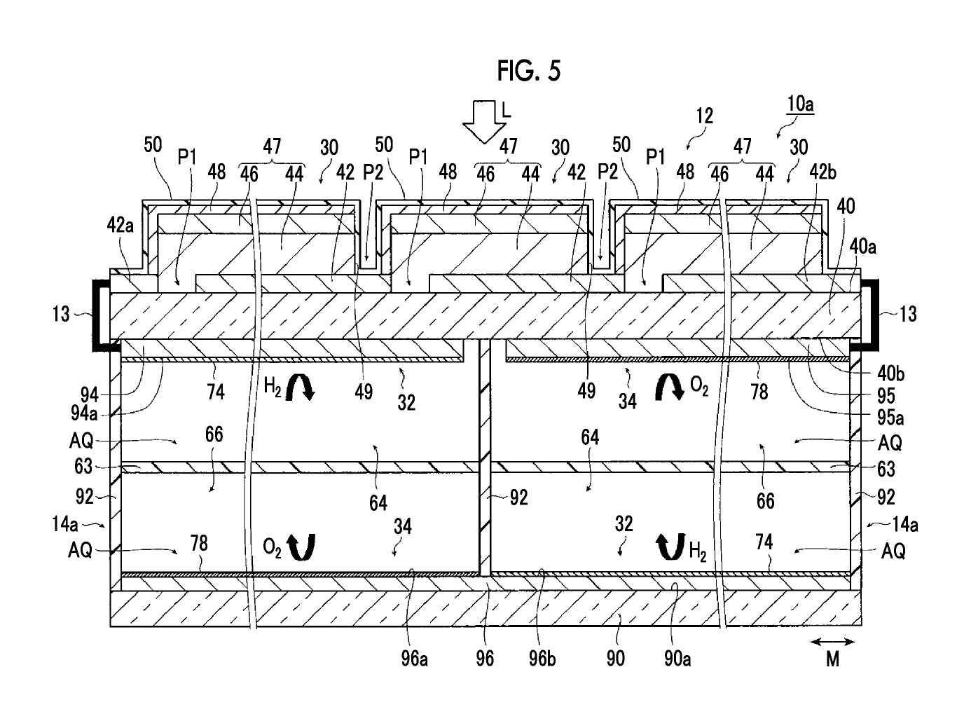

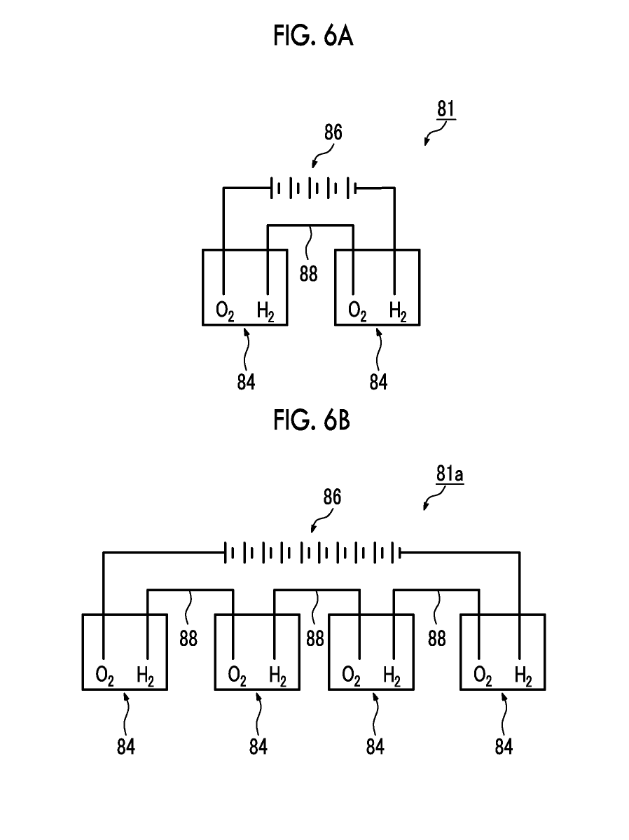

FIG. 4 is a schematic plan view illustrating the configuration of a water electrolysis system of the second embodiment of the invention. FIG. 5 is a schematic sectional view of main parts of the water electrolysis system of the second embodiment of the invention illustrated in FIG. 4. FIG. 6A is an equivalent circuit diagram of the water electrolysis system of the embodiment of the invention, and FIG. 6B is an equivalent circuit diagram of another example of the water electrolysis system of the embodiment of the invention.

In the present embodiment, the same structures as those of the water electrolysis system 10 of the first embodiment illustrated in FIGS. 1 and 2 and the same structures as the equal circuit 80 illustrated in FIG. 3 will be designated by the same reference signs, and the detailed description thereof will be omitted.

As illustrated in FIG. 5, a water electrolysis system 10a (hereinafter simply referred to as a system 10a) of the present embodiment is different from the system 10 in the first embodiment in that only the photoelectric conversion units 12 are arranged on the surface 40a of the insulating substrate 40 instead of the integrated structure in which the photoelectric conversion units 12 and the electrolyte cells 14 are provided on the surface 40a of the planar insulating substrate 40. Additionally, there is a difference in that an electrolyte cells 14a are provided on a rear surface 40b of the insulating substrate 40 opposite to the side where the photoelectric conversion units 12 receive light, instead of being provided on the surface 40a of the insulating substrate 40. Additionally, there is a difference that the photoelectric conversion elements 30 of the photoelectric conversion unit 12 located at the respective ends in the direction M are not connected together but back electrodes 42a and 42b and the electrolyte cells 14a are connected together with wiring 13. Moreover, as illustrated in FIG. 4, connecting positions of the supply pipe 17, the recovery pipe 19, the pipe 21 for hydrogen, and the pipe 23 for oxygen differ. Since the system 10a has the same configuration as the system 10 illustrated in FIGS. 1 and 2 in respects other than these, the detailed description thereof will be omitted.

In the system 10a, as illustrated in FIG. 5, a flat plate-shaped insulating base material 90 is arranged parallel to the rear surface 40b of the insulating substrate 40 while facing the rear surface 40b of the insulating substrate 40. A plurality of wall members 92, and three wall members 92 in the example of FIG. 5 are provided between the rear surface 40b of the insulating substrate 40 and a surface 90a of the insulating base material 90. Accordingly, two electrolyte cells 14a are constructed. The electrolyte cells 14a constitute gas generation regions.

Within each electrolyte cell 14a, a gas separation membrane 63 is provided parallel to the rear surface 40b of the insulating substrate 40 and the surface 90a of the insulating base material 90 between the insulating substrate 40 and the insulating base material 90. Accordingly, the electrolyte cell 64 for hydrogen and the electrolyte cell 66 for oxygen are separated from each other in a lamination direction of respective layers of the photoelectric conversion unit 12 within the electrolyte cell 14a.

The electrolyte cell 64 for hydrogen has the hydrogen gas recovery part 20 connected thereto via the pipe 21 for hydrogen. The electrolyte cell 66 for oxygen has the oxygen gas recovery part 22 connected thereto via the pipe 23 for oxygen. The supply part 16 is connected to the electrolyte cell 64 for hydrogen and the electrolyte cell 66 for oxygen via the supply pipe 17, and the aqueous electrolyte solution AQ is supplied to the electrode cells.

Here, in the photoelectric conversion unit 12, the back electrode 42a is a negative electrode (a cathode for electrolysis) and the back electrode 42b is a positive electrode (an anode for electrolysis). For this reason, the insulating substrate 40 side of the electrolyte cell 14a on the back electrode 42a side is the electrolyte cell 64 for hydrogen. Within the electrolyte cell 64 for hydrogen, a hydrogen generating electrode 94 is provided on the rear surface 40b of the insulating substrate 40.

The hydrogen generating electrode 94 is electrically connected to the back electrode 42a with the wiring 13. The catalyst electrode 74 for generation of hydrogen is formed on a surface 94a of the hydrogen generating electrode 94. Accordingly, the hydrogen gas generating part 32 is constructed. Meanwhile, the insulating base material 90 side of the electrolyte cell 14a on the back electrode 42a side is the electrolyte cell 66 for oxygen.

The insulating substrate 40 side of the electrolyte cell 14a on the back electrode 42b side is the electrolyte cell 66 for oxygen. Within the electrolyte cell 66 for oxygen, the oxygen generating electrode 95 is provided on the rear surface 40b of the insulating substrate 40. The oxygen generating electrode 95 is electrically connected to the back electrode 42b with the wiring 13. The catalyst electrode 78 for generation of oxygen is formed on a surface 95a of the oxygen generating electrode 95. Accordingly, the oxygen gas generating part 34 is constructed. Meanwhile, the insulating base material 90 side of the electrolyte cell 14a on the back electrode 42b side is the electrolyte cell 64 for hydrogen.

The electrolyte cell 64 for hydrogen and the electrolyte cell 66 for oxygen on the side of the insulating base material 90 are provided with a common conductive member 96. The common conductive member 96 is arranged on the surface 90a of the insulating base material 90, for example, the common conductive member 96 is grounded. The catalyst electrode 74 for generation of hydrogen is formed on a surface 96b of the common conductive member 96 corresponding to the electrolyte cell 64 for hydrogen. The catalyst electrode 78 for generation of oxygen is formed on a surface 96a of the common conductive member 96 corresponding to the electrolyte cell 66 for oxygen. The common conductive member 96 serves as both a hydrogen gas generating electrode and an oxygen gas generating electrode. In this way, the hydrogen gas generating part 32 and the oxygen gas generating part 34 are respectively constructed in the electrolyte cell 64 for hydrogen and the electrolyte cell 66 for oxygen.

In this way, the electrolyte cell 14a includes the hydrogen generating electrode 94 for generating oxygen gas and the oxygen generating electrode 95 for generating hydrogen gas as the gas generating electrodes.

Both of the hydrogen generating electrode 94 and the oxygen generating electrode 95 are made of flat plate-shaped conductors. The hydrogen generating electrode 94 and the oxygen generating electrode 95 face each other with the gas separation membrane 63 interposed therebetween, are provided parallel to the rear surface 40b of the insulating substrate 40.

Hydrogen gas is generated in the electrolyte cell 14a due to a potential difference between the hydrogen generating electrode 94 of the electrolyte cell 64 for hydrogen, and the common conductive member 96. Additionally, oxygen gas is generated due to a potential difference between the oxygen generating electrode 95 of the electrolyte cell 66 for oxygen, and the common conductive member 96.

In addition, the gas separation membrane 63 provided in each electrolyte cell 14a may be provided to separate the inside of each electrolyte cell 14a into the electrolyte cell 64 for hydrogen and the electrolyte cell 66 for oxygen in order to pass hydroxy ions and hydrogen ions therethrough so that the hydroxy ions (pH also increases) that has increased due to the generation of hydrogen within the electrolyte cell 64 for hydrogen and the hydrogen ions (pH decreases) that has increased due to the generation of oxygen within the electrolyte cell 66 for oxygen neutralize. In this case, the gas separation membrane 63, similar to the partition wall 62, is configured to have, for example, ion permeability and gas non-permeability. Specifically, the gas separation membrane is made of, for example, an ion exchange membrane, a ceramic filter, porous glass, or the like. The thickness of the gas separation membrane 63 is not particularly limited, and is preferably 10 μm to 1000 μm.

Since the insulating base material 90 that constitutes each electrolyte cell 14a can be made of the same material as that of the insulating substrate 40, the detailed description thereof will be omitted.

The configuration of the wall member 92 is not particularly limited if the wall member can contain the aqueous electrolyte solution AQ without leaking this solution and does not react with hydrogen gas and oxygen gas.

Since the hydrogen generating electrode 94, the oxygen generating electrode 95, and the common conductive member 96 can be made of the same material as that of the back electrode 42, the detailed description thereof will be omitted.

The system 10a can be expressed as an equal circuit 81 as illustrated in FIG. 6A, if illustrated as an electric circuit. In the equal circuit 81, the electrolyte cell parts 84 are equivalent to the electrolyte cells 14a illustrated in FIG. 5. The electromotive force part 86 connected to the electrolyte cell parts 84 is equivalent to the photoelectric conversion unit 12 illustrated in FIG. 4. One battery of the electromotive force part 86 is equivalent to one photoelectric conversion element 30. A wiring part 88 is equivalent to the common conductive member 96 illustrated in FIG. 5. In the system 10a, the respective electrolyte cells 14a are connected in series.

In the equal circuit 81 illustrated in FIG. 6A, five photoelectric conversion elements 30 are connected in series. If the electromotive force of one photoelectric conversion element 30 is 0.8 V, the electromotive force of the entire system 10a is 4 V. The voltage applied to each of the two electrolyte cell parts 84 is 4 V/2 pieces, that is, 2 V/1 piece. Here, since the voltage required for electrolyzing water is 1.8 V as described above, 0.2 V is surplus for one electrolyte cell 14a and an energy loss equivalent thereto occurs.

In the system 10a, if ten photoelectric conversion elements 30 are connected in series as illustrated in FIG. 6B, the voltage applied the electrolyte cells 14 can be 2 V/1 piece even in a case where four electrolyte cells 14a are provided.

In the system 10a, the photoelectric conversion unit 12 is irradiated with light L and the aqueous electrolyte solution AQ is supplied from the supply part 16 to each electrolyte cell 14. As a result, the aqueous electrolyte solution AQ is decomposed in the electrolyte cell 64 for hydrogen of each electrolyte cell 14 and thereby hydrogen gas is generated, and the aqueous electrolyte solution AQ is decomposed in the electrolyte cell 66 for oxygen and thereby oxygen gas is generated. The hydrogen gas is recovered by the hydrogen gas recovery part 20 via the pipe 21 for hydrogen. The oxygen gas is recovered by the oxygen gas recovery part 22 via the pipe 23 for oxygen.

Even in the system 10a, by dividing the photoelectric conversion units 12 and the gas generating electrodes, it is unnecessary to dip a photoelectric conversion portion in the aqueous electrolyte solution AQ, and degradation of performance caused by immersion can be avoided.

Moreover, by providing the electrolyte cell 14a on the rear surface 40b side of the insulating substrate 40 opposite to the light-receiving surface, the area of the electrolyte cell 64 for hydrogen and the electrolyte cell 66 for oxygen can be increased, and the area of the hydrogen generating electrode 94 and the oxygen generating electrode 95 can be increased. Accordingly, the amount of gas generated can be increased.

In addition, even in the system 10a of the present embodiment, the same effects as those of the system 10 other than the above can be obtained.

The invention is basically configured as described above. Although the water electrolysis system of the invention has been described above in detail, the invention is not limited to the above embodiments, and various improvements or modifications may be made without departing from the scope of the invention.

### EXPLANATION OF REFERENCES

10, 10a: water electrolysis system (electrolysis system)
12: photoelectric conversion unit
14: electrolyte cell
16: supply part
18: recovery part
30: photoelectric conversion element
32: hydrogen gas generating part
34: oxygen gas generating part
40: insulating substrate
42: back electrode
44: photoelectric conversion layer
46: buffer layer
48: transparent electrode
50: protective layer
62: partition wall
63: gas separation membrane
64: electrolyte cell for hydrogen
66: electrolyte cell for oxygen
70, 76: region
72: functional layer
80: equal circuit
82 power source part
84: electrolyte cell part
86: electromotive force part
90: insulating base material
92: wall member
94: hydrogen generating electrode
95: oxygen generating electrode
96: common conductive member
100: related-art water electrolysis device

What is claimed is:

1. A water electrolysis system that decomposes an aqueous electrolyte solution into hydrogen and oxygen using light, the water electrolysis system comprising:
a plurality of photoelectric conversion units that have at least one photoelectric conversion element and receive light to generate electrical energy; and
a plurality of electrolyte cells that includes gas generating electrodes in which hydrogen gas and oxygen gas are generated by electrolyzing the aqueous electrolyte solution using the electrical energy obtained by the photoelectric conversion units,
wherein the photoelectric conversion units and the electrolyte cells are electrically connected in series, and
wherein the photoelectric conversion units or the electrolyte cells located at respective ends in an arrangement state are electrically connected together.

2. The water electrolysis system according to claim 1,
wherein the photoelectric conversion units are arranged on the surface of an insulating substrate,
wherein the electrolyte cells are arranged on a rear surface of the insulating substrate opposite to a side where the photoelectric conversion units receive light, and
wherein a hydrogen generating electrode for generating the hydrogen gas and an oxygen generating electrode for generating the oxygen gas are included as the gas generating electrodes, and the hydrogen generating electrode and the oxygen generating electrode face each other.

3. The water electrolysis system according to claim 1,
wherein each of the photoelectric conversion units has a plurality of photoelectric conversion elements connected in series.

4. The water electrolysis system according to claim 2,
wherein each of the photoelectric conversion units has a plurality of photoelectric conversion elements connected in series.

5. The water electrolysis system according to claim 1,
wherein each of the photoelectric conversion elements includes an inorganic semiconductor film having a pn junction.

6. The water electrolysis system according to claim 2,
wherein each of the photoelectric conversion elements includes an inorganic semiconductor film having a pn junction.

7. The water electrolysis system according to claim 3,
wherein each of the photoelectric conversion elements includes an inorganic semiconductor film having a pn junction.

8. The water electrolysis system according to claim 4,
wherein an absorption wavelength end of the inorganic semiconductor film is 800 nm or more.

9. The water electrolysis system according to claim 4,
wherein the inorganic semiconductor film includes a CIGS compound semiconductor.

10. The water electrolysis system according to claim 5,
wherein the inorganic semiconductor film includes a CIGS compound semiconductor.

11. The water electrolysis system according to claim 4,
wherein the inorganic semiconductor film includes a CZTS compound semiconductor.

12. The water electrolysis system according to claim 5,
wherein the inorganic semiconductor film includes a CZTS compound semiconductor.

13. The water electrolysis system according to claim 1,
wherein the gas generating electrodes are provided with a catalyst electrode used for generation of the hydrogen gas, and the catalyst electrode used for generation of the hydrogen gas is made of Pt, a substance containing Pt, or Rh.

14. The water electrolysis system according to claim 2,
wherein the gas generating electrodes are provided with a catalyst electrode used for generation of the hydrogen gas, and the catalyst electrode used for generation of the hydrogen gas is made of Pt, a substance containing Pt, or Rh.

15. The water electrolysis system according to claim 1,
wherein the gas generating electrodes are provided with a catalyst electrode used for generation of the oxygen gas, and the catalyst electrode used for generation of the oxygen gas is made of CoOₓ or IrO₂.

16. The water electrolysis system according to claim 2,
wherein the gas generating electrodes are provided with a catalyst electrode used for generation of the oxygen gas, and the catalyst electrode used for generation of the oxygen gas is made of CoOₓ or IrO₂.

17. The water electrolysis systems according to claim 1,
wherein when the plurality of photoelectric conversion units are irradiated with light, the amounts of generated currents generated in the respective photoelectric conversion units are equal.

18. The water electrolysis systems according to claim 2,
wherein when the plurality of photoelectric conversion units are irradiated with light, the amounts of generated currents generated in the respective photoelectric conversion units are equal.

19. The water electrolysis systems according to claim 3,
wherein when the plurality of photoelectric conversion units are irradiated with light, the amounts of generated currents generated in the respective photoelectric conversion units are equal.

20. The water electrolysis systems according to claim 4,
wherein when the plurality of photoelectric conversion units are irradiated with light, the amounts of generated currents generated in the respective photoelectric conversion units are equal.
